(19) United States
(12) Patent Application Publication
(10) Pub. No.: US 2026/0011611 A1
(43) Pub. Date: Jan. 8, 2026

(54) SEMICONDUCTOR DEVICES WITH DIE OVERTHINNING DETECTION CIRCUITRY, AND ASSOCIATED SYSTEMS, DEVICES, AND METHODS

(71) Applicant: Micron Technology, Inc., Boise, ID (US)

(72) Inventor: Christopher J. Larsen, Boise, ID (US)

(21) Appl. No.: 19/239,914

(22) Filed: Jun. 16, 2025

Related U.S. Application Data
(60) Provisional application No. 63/667,690, filed on Jul. 3, 2024.

(51) Int. Cl. H01L 21/66

(52) U.S. Cl. CPC H01L 22/34; H01L 22/12; H01L 22/14; H01L 22/32

(57) ABSTRACT

Semiconductor devices with die overthinning detection circuitry (and associated systems, devices, and methods) are disclosed herein. In one embodiment, a semiconductor die includes a substrate, a triple well structure positioned at least partially within the substrate, and circuitry. The triple well structure can form a depletion region within the substrate, and the circuitry can be configured to capture a measurement of an amount of leakage current from the depletion region while a reverse bias is applied across the triple well structure. In some embodiments, the reverse bias can be applied across the triple well structure using part of a metallization die border of the semiconductor die. In these and other embodiments, measurement of the amount of leakage current can be used to detect that the semiconductor die is defective (e.g., overthinned, overpolished).

### CROSS-REFERENCE TO RELATED APPLICATION(S)

The present application claims priority to U.S. Provisional Patent Application No. 63/667,690, filed Jul. 3, 2024, the disclosure of which is incorporated herein by reference in its entirety.

### TECHNICAL FIELD

The present technology is generally related to semiconductor devices. For example, several embodiments of the present technology relate to semiconductor devices with circuitry configured to detect die overthinning/overpolishing, and associated systems, devices, and methods.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM), NAND memory, and/or high-bandwidth memory (HBM), can utilize electrical energy to store and access data.

With technological advancements in embedded systems and increasing applications, the market is continuously looking for faster, more efficient, and smaller devices. To meet market demands, semiconductor devices are being pushed to the limit with various improvements. Improving semiconductor devices, generally, may include increasing circuit density, increasing circuit capacity, increasing operating speeds (or otherwise reducing operational latency), increasing reliability, increasing data retention, reducing power consumption, reducing manufacturing costs, or reducing device size, among other metrics. Attempts, however, to meet the market demands, such as by decreasing die thicknesses, can often introduce challenges in other aspects, such as maintaining device reliability and detecting device defects.

### BRIEF DESCRIPTION OF THE DRAWINGS

Many aspects of the present disclosure can be better understood with reference to the following drawings. The components in the drawings are not necessarily to scale. Instead, emphasis is placed on clearly illustrating the principles of the present disclosure. The drawings should not be taken to limit the disclosure to the specific embodiments depicted, but are for explanation and understanding only.

FIG. 1A is a partially schematic plan view of a semiconductor wafer configured in accordance with various embodiments of the present technology.

FIG. 1B is a partially schematic plan view of a semiconductor die configured in accordance with various embodiments of the present technology.

FIGS. 2A and 2B are partially schematic, cross-sectional side views of a semiconductor die configured in accordance with various embodiments of the present technology.

FIG. 3 is a partially schematic diagram of die overthinning detection circuitry implemented with the semiconductor die of FIGS. 2A and 2B and configured in accordance with various embodiments of the present technology.

FIG. 4 is a partially schematic, cross-section side view of a semiconductor device configured in accordance with various embodiments of the present technology.

FIG. 5 is a flow diagram illustrating a method of operating a semiconductor die in accordance with various embodiments of the present technology.

FIG. 6 is a block diagram of a system having a semiconductor device configured in accordance with embodiments of the present technology.

### DETAILED DESCRIPTION

As described in more detail below, several embodiments of the present disclosure are generally directed to semiconductor dies that each include circuitry configured to (a) apply a voltage (e.g., a reverse bias) across a triple well structure of the semiconductor die and/or (b) measure an amount of leakage current from a depletion region formed by the triple well structure in the semiconductor die. Because an amount of leakage current from defects in the depletion region is expected to increase when the semiconductor die is overthinned or overpolished into (or too near) the depletion region, the measured amount of leakage current can provide an indication of whether the semiconductor die has been overthinned or overpolished, or of whether the semiconductor die poses reliability issues/concerns. When the measured amount of leakage current indicates that the semiconductor die is defective (e.g., is overthinned, is overpolished, poses reliability issues/concerns), the semiconductor die can be discarded (e.g., before being packaged or implemented into a stack of semiconductor dies) and/or disabled (e.g., such that a semiconductor device including a stack of semiconductor dies incorporating the defective semiconductor die can continue to operate with the remaining non-defective/properly-functioning semiconductor dies of the stack).

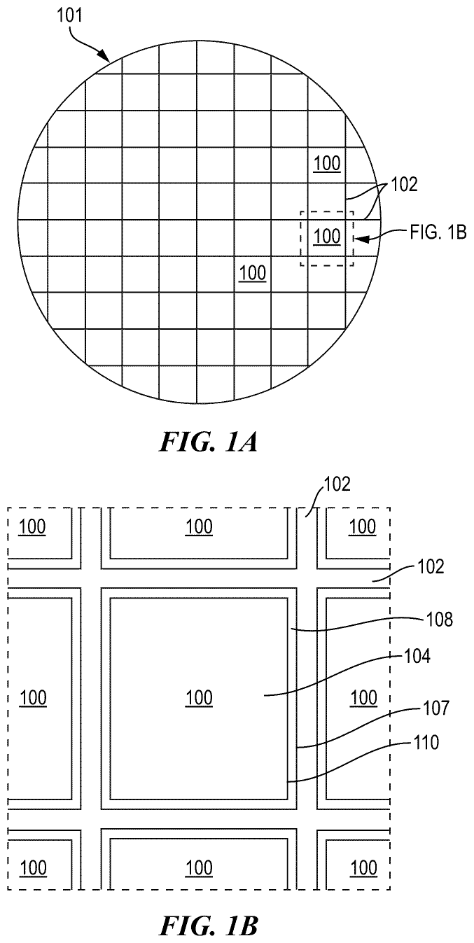

Specific details of several embodiments of the present technology are described herein with reference to FIGS. 1A-6. For the sake of clarity and example, the present technology is primarily described below in the context of semiconductor devices and dies (e.g., memory devices and dies) including NAND storage elements. Semiconductor devices and dies configured in accordance with other embodiments of the present technology, however, can include (a) other types of circuits (e.g., non-memory devices/dies); and/or (b) memory devices/dies including other types of storage elements (in addition to or in lieu of DRAM storage elements and/or NAND storage elements), such as dynamic random-access memory (DRAM) storage elements, static random-access memory (SRAM) storage elements, NOR storage elements, phase change memory (PCM) storage elements, ferroelectric random-access memory (FeRAM) storage elements, resistive random-access memory (RRAM) storage elements, and/or magnetic random-access memory (MRAM) storage elements, among others. Moreover, a person of ordinary skill in the art will understand that embodiments of the present technology can have different configurations, components, and/or procedures than those shown or described herein, and/or that these and other embodiments can be without several of the configurations, components, and/or procedures shown or described herein without deviating from the present technology.

As used herein, the terms “vertical,” “lateral,” “upper,” “lower,” “top,” and “bottom” can refer to relative directions or positions of features in systems, devices, and circuits in view of the orientations shown in the drawings. For example, “bottom” can refer to a feature positioned closer to the bottom of a page than another feature. These terms, however, should be construed broadly to include systems, devices, and circuits having other orientations, such as inverted or inclined orientations where top/bottom, over/under, above/below, up/down and left/right can be interchanged depending on the orientation.

Many semiconductor devices utilize triple well technology in corresponding semiconductor dies to isolate transistors, memory arrays, and other components from bulk substrates. As a specific example, NAND memory devices commonly employ triple well technology to isolate NAND memory arrays from bulk substrates (e.g., p-substrates). Isolation of a NAND memory array from a bulk substrate can facilitate using high voltages to program and erase memory cells of the NAND memory array.

To meet market demands for smaller devices, the bulk substrates of semiconductor dies are commonly thinned (typically at the wafer level) before packaging. Thinning the bulk substrates of semiconductor dies can, for example, enable a greater number of semiconductor dies to be stacked and/or packaged together. When, however, a semiconductor die employs triple well technology and the bulk substrate is overthinned or overpolished, defects can occur in a depletion region of the triple well and/or a large amount of leakage current from the depletion region can be observed (e.g., from preexisting defects in the depletion region and/or from new defects in the depletion region created by the overthinning/overpolishing). The large amount of leakage current can, in turn, result in various problems. For example, in a NAND memory device, high leakage current may prevent or hinder the NAND memory device from reaching voltage levels required to properly perform program or erase operations on memory cells. This may lead to trap-up in the memory cells and, in turn, to the stepping up of voltage levels needed to properly erase the memory cells, thereby posing reliability problems. As another example, after an overthinned semiconductor die is packaged with other semiconductor dies of a semiconductor device, the large amount of leakage current from the overthinned semiconductor die can result in the semiconductor device failing desired specifications (e.g., by exhibiting too high of standby current Isb and/or too high of active current or peak current Icc). In turn, the entire semiconductor device is typically discarded, constituting a waste of resources as the semiconductor device likely includes several dies that are not overthinned and are functioning properly.

To address these concerns, the present technology is generally directed to semiconductor devices that include circuitry usable to detect when a semiconductor die has been overthinned or overpolished, or when leakage current from a depletion region of the semiconductor die is too high and poses reliability issues/concerns. For example, in several embodiments of the present technology, a semiconductor die includes circuitry configured to apply a voltage (e.g., a reverse bias) across a triple well structure of the semiconductor die and/or (b) measure (e.g., while the voltage is applied across the triple well structure) an amount of leakage current from a depletion region formed by the triple well structure in the semiconductor die. The circuitry can include a voltage supply (e.g., a high-voltage pump) that is configured to apply the voltage across the triple well structure and/or a current meter that is configured to measure the amount of leakage current.

In some embodiments, the voltage can be applied across the triple well structure using a first contact coupled to the triple well structure at a first side of a substrate of the semiconductor die and a second contact coupled to the triple well structure at a second side of the substrate opposite the first side. The semiconductor die can include a metallization die border that traces or is generally positioned along a perimeter of the semiconductor die. In some embodiments, the first contact can be part of the metallization die border. In other embodiments, the first contact can be separate from the metallization die border.

As discussed above, because an amount of leakage current from defects in the depletion region is expected to increase when the semiconductor die is overthinned or overpolished into (or too near) the depletion region formed by the triple well structure in the semiconductor die, the amount of leakage current measured by the circuitry can provide an indication of whether the semiconductor die has been overthinned or overpolished. For example, the measured amount of leakage current can be compared to a threshold leakage current value. Continuing with this example, when the measured amount of leakage current is greater than (or equal to) the threshold leakage current value, the semiconductor die can be identified as defective (e.g., as overthinned, as overpolished, or as otherwise posing reliability issues/concerns).

In some embodiments, the circuitry can be used to determine whether the semiconductor die is defective prior to the semiconductor die being packaged and/or implemented into a stack of semiconductor dies. For example, the circuitry can be used to determine whether the semiconductor die is defective at the wafer-level (before the semiconductor die is singulated from a wafer) and/or at the die-level (after the semiconductor die is singulated from a wafer but before being packaged and/or positioned within a stack). In these embodiments, when the semiconductor die is identified as defective, the semiconductor die can be discarded before being packaged and/or implemented into a stack.

In these and other embodiments, the circuitry can be used to determine whether the semiconductor die is defective after the semiconductor die is packaged and/or implemented into a stack of semiconductor dies. For example, the semiconductor die can be implemented in a stack including a plurality of semiconductor dies, and each semiconductor die of the plurality can include a unique instance of (e.g., dedicated) overthinning detection circuitry. In these embodiments, each instance of the circuitry can be used to determine whether the corresponding semiconductor die of the stack is overthinned, overpolished, and/or exhibiting a large amount of leakage current that poses reliability issues/concerns. In turn, the semiconductor die(s) of the stack that are identified as defective can be individually disabled or turned off, and a semiconductor device that includes the stack can continue to operate with a reduced number of enabled/properly-functioning semiconductor dies in the stack.

The present technology is therefore expected to offer several advantages. For example, die overthinning detection circuitry configured in accordance with several embodiments of the present technology can include or leverage several components (e.g., high-voltage pumps, metallization die borders) that are commonly found on many semiconductor dies. As such, the die overthinning detection circuitry of at least these embodiments is expected to provide die overthinning/overpolishing detection with a small or minimal increase in die size or area. As another example, in embodiments that utilize part of the metallization die border of a semiconductor die to apply a voltage across a triple well structure of the semiconductor die, the metallization die border spans a large area of the semiconductor die as it is generally positioned along the perimeter of the semiconductor die. As such, die overthinning detection circuitry configured in accordance with at least these embodiments of the present technology is expected to detect overthinning, overpolishing, and/or large leakage current across a large area of the die.

As still another example, die overthinning detection circuitry configured in accordance with various embodiments of the present technology can be performed at the wafer-level, at the die-level, post-packaging, and/or after implementing the semiconductor die in a stack. When used to detect defective semiconductor dies prior to packaging and/or prior to implementing the semiconductor dies in a stack, defective semiconductor dies can be identified and discarded early in the manufacturing and/or assembly processes such that they are not incorporated into assembled devices and systems. When used to detect defective semiconductor dies post-packaging and/or after implementing the semiconductor dies in a stack, individual semiconductor dies can be identified as defective and/or disabled, obviating the practice of discarding entire semiconductor devices that include other non-defective/properly-functioning semiconductor dies (thereby conserving resources).

FIG. 1A is a partially schematic plan view of a semiconductor wafer 101 configured in accordance with various embodiments of the present technology. As shown, the semiconductor wafer 101 includes a plurality of semiconductor dies 100 separated from one another by scribe line regions 102 (also referred to herein as “dicing streets”). The scribe line regions 102 are located about the perimeters of the semiconductor dies 100, and a saw or laser can be used to cut the semiconductor wafer 101 along the scribe line regions 102 to singulate the semiconductor dies 100. In the illustrated embodiment, the semiconductor dies 100 are rectangular or square in shape. In other embodiments, the semiconductor dies 100 can have other suitable shapes.

FIG. 1B is a partially schematic plan view of a semiconductor die 100 of the semiconductor wafer 101 of FIG. 1A. As shown, the semiconductor die 100 includes an active or central region 104, a perimeter region 108 surrounding the central region 104, and a metallization die border 110 positioned about the perimeter of the semiconductor die 100. In some embodiments, the semiconductor die 100 can additionally include a conductive barrier structure 107.

The metallization die border 110 (also referred to herein as a “die seal”) can be a conductive path or bus. For example, the metallization die border 110 can include a continuous band of middle layers of the semiconductor die 100. The middle layers can include vias, interconnects, metal lines, and/or electrical contacts, among other conductive structures. In some embodiments, the metallization die border 110 can be at least partially elevated (e.g., relative to the central region 104) and/or can be used for electrical fuse operations. In these and other embodiments, the metallization die border 110 can be coupled to one or more external pins or terminals (not shown), such as for applying a voltage to the metallization die border 110 to measure leakage current (as discussed in greater detail below). In these and still other embodiments, the metallization die border 110 can be used to prevent or hinder mobile contaminants (e.g., die cracks) from entering the central region 104 of the semiconductor die 100 and/or to detect the presence of such mobile contaminants.

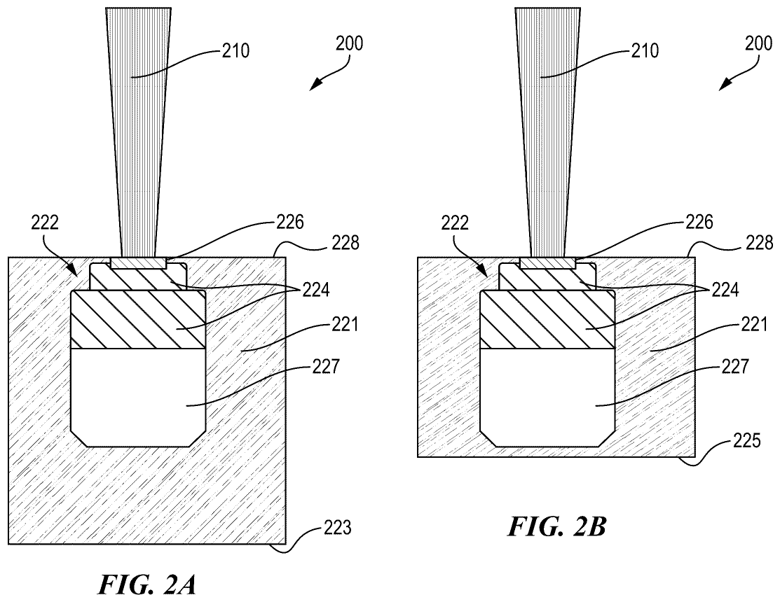

FIGS. 2A and 2B are partially schematic, cross-sectional side views of a semiconductor die 200 configured in accordance with various embodiments of the present technology. The semiconductor die 200 can be an example of one of the semiconductor dies 100 of FIGS. 1A and 1B, or of other semiconductor dies configured in accordance with embodiments of the present technology. As shown, the semiconductor die 200 includes a substrate 221, a triple well structure 222 formed in the substrate 221, and a conductive contact 210 within (e.g., coupled to) the triple well structure 222.

In some embodiments, the substrate 221 can be a p-type substrate. In these embodiments, the triple well structure 222 can include the p-type substrate 221, a deep n-well 224, and an isolated p-well (not shown) within the deep n-well 224. For example, the triple well structure 222 can be an NMOS triple well structure. In other embodiments, the triple well structure 222 can include the p-type substrate 221 and an n-well 224. For example, the triple well structure 222 can be a PMOS triple well structure. In either implementation, the triple well structure 222 can include one or more p-n junctions. As a result, a depletion region 227 can be formed within the semiconductor die 200.

The triple well structure 222 can be used to isolate transistors, memory arrays, and/or other components from the bulk substrate 221. As a specific example, in embodiments in which the semiconductor die 200 includes a NAND memory array, the triple well structure 222 can be used to isolate the NAND memory array from the substrate 221, such as to facilitate using high voltages to program and erase memory cells of the NAND memory array.

The semiconductor die 200 further includes a heavily doped region 226. In some embodiments, the heavily doped region 226 can be a n+ region. In other embodiments, the heavily doped region 226 can be a p+ region.

As discussed above, the conductive contact 210 (also referred to herein as a “first contact”) can be positioned within the triple well structure 222. For example, the conductive contact 210 can be electrically coupled to the heavily doped region 226 and/or to the n-well 224 (e.g., directly or via the heavily doped region 226). In some embodiments, the conductive contact 210 can be part of a metallization die border of the semiconductor die 200 (e.g., part of the metallization die border 110 of the semiconductor die 100 of FIG. 1B). In other embodiments, the conductive contact 210 can be a contact that is separate from the metallization die border of the semiconductor die 200. For example, the conductive contact 210 can be a contact that is positioned about or along a perimeter of a central region (e.g., the central region 104 of FIG. 1B) of the semiconductor die 200, such as at a location proximate to but separate from the metallization die border of the semiconductor die 200. As another example, the conductive contact 210 can be a contact that is positioned within, or that crosses, a portion of the central region of the semiconductor die 200.

As shown in FIG. 2A, the substrate 221 includes a top surface 228 (also referred to herein as a “first surface,” a “top side,” or a “top surface”) and a bottom surface 223 opposite the top surface 228. To facilitate stacking and/or packaging a greater number of semiconductor devices together, the semiconductor die 200 can be thinned before stacking or packaging the semiconductor die 200 with other semiconductor devices. For example, the semiconductor die 200 can be thinned by removing (e.g., via a backgrind process) a backside portion of the substrate 221 such that, after the thinning process is complete, the substrate 221 includes a bottom surface 225 that (as shown in FIG. 2B) is positioned closer to the top surface 228 than the bottom surface 223 of FIG. 2A. The bottom surface 225 is also referred to herein as a “second surface,” a “second side,” or a “second surface.” In some embodiments, the thinning process can occur at a wafer-level (e.g., before the semiconductor die 200 is singulated from a wafer).

Occasionally, the semiconductor die 200 can be overthinned. For example, the semiconductor die 200 can be overthinned such that the bottom surface 225 of the substrate 221 is positioned within or too near the depletion region 227 formed by the triple well structure 222. Such overthinning of the substrate 221 can cause defects to occur in the depletion region 227 that can lead to a large amount of leakage current from the depletion region 227. The large amount of leakage current can, in turn, result in various problems. For example, in embodiments in which the semiconductor die 200 includes a NAND memory array, high leakage current may prevent or hinder the semiconductor die 200 from reaching voltage levels required to properly perform program or erase operations on memory cells of the NAND memory array. This may lead to trap-up in the memory cells and, in turn, to the stepping up of voltage levels needed to properly erase the memory cells, thereby posing reliability problems. As another example, after an overthinned semiconductor die is packaged with other semiconductor dies of a semiconductor device, the large amount of leakage current from the overthinned semiconductor die can result in the semiconductor device failing desired specifications (e.g., by exhibiting too high of standby current Isb and/or too high of active current or peak current Icc). Overthinning detection circuitry can therefore be used to detect when the semiconductor die 200 has been overthinned.

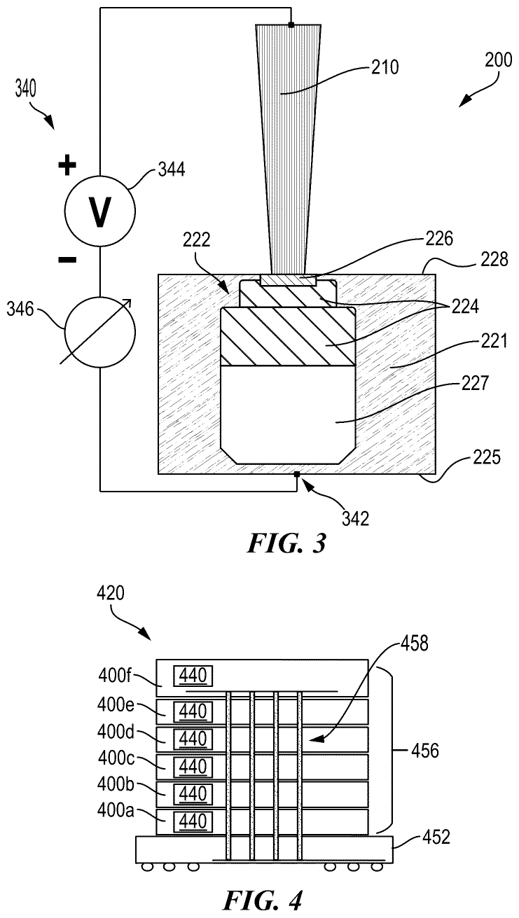

FIG. 3 is a partially schematic diagram of die overthinning detection circuitry 340 configured in accordance with various embodiments of the present technology. More specifically, FIG. 3 illustrates the die overthinning detection circuitry 340 implemented with the semiconductor die 200 of FIGS. 2A and 2B. As shown, the die overthinning detection circuitry 340 includes a voltage supply 344, a current meter 346, and a contact 342 (also referred to herein as a “second contact”). The contact 342 is coupled to the bottom surface 225 of the substrate 221 (e.g., beneath or in line with the depletion region 227). A first terminal (e.g., a positive terminal) of the voltage supply 344 is coupled to the conductive contact 210, and a second terminal (e.g., a negative terminal) of the voltage supply 344 is coupled to the contact 342 via the current meter 346.

The voltage supply 344 is configured to apply a reverse bias to the triple well structure 222 of the semiconductor die 200. For example, the voltage supply 344 can be configured to supply a voltage on the order of 20V or greater (e.g., 30V or greater) between the conductive contact 210 of the semiconductor die 200 and the contact 342 at the bottom surface 225 of the substrate 221. In embodiments in which the semiconductor die 200 includes a NAND memory array, the voltage supplied by the voltage supply 344 can mimic a voltage used during erase operations of memory cells of the NAND array.

In some embodiments, the semiconductor die 200 can include the voltage supply 344 and/or the current meter 346. For example, the voltage supply 344 can be a high-voltage pump included in or on the semiconductor die 200. In other embodiments, the voltage supply 344 and/or the current meter 346 can be positioned external to the semiconductor die 200. For example, the voltage supply 344 can be coupled to the conductive contact 210, the current meter 346, and/or the contact 342 via external terminals or pins (not shown) of the semiconductor die 200. Similarly, the current meter 346 can be coupled to the conductive contact 210, the voltage supply 344, and/or the contact 342 via external terminals or pins (not shown) of the semiconductor die 200. In these and other examples, the voltage supply 344 and/or the current meter 346 can be positioned within a base die or logic die of a semiconductor device that includes the semiconductor die 200.

The current meter 346 is configured to measure an amount of leakage current from the depletion region 227 of the semiconductor die 200 when the voltage supply 344 supplies a reverse bias to the triple well structure 222 of the semiconductor die 200. More specifically, as discussed above, backgrind encroachment and/or overpolishing into a depletion region of a triple well structure can cause defects in the depletion region. In turn, the defects can cause a relatively large amount of leakage current from the depletion region in comparison to a depletion region devoid of defects. Therefore, leakage current measurements captured by the current meter 346 when the voltage supply 344 supplies a reverse bias to the triple well structure 222 of the semiconductor die 200 can be used as an indication of whether the semiconductor die 200 has been overthinned/overpolished. In particular, leaker current measurements at or above a threshold value can indicate that the semiconductor die 200 has been overthinned/overpolished and poses reliability concerns, and/or current measurements at or below the threshold value can indicate that the semiconductor die 200 has not been overthinned/overpolished.

FIG. 4 is a partially schematic, cross-sectional side view of a semiconductor device 420 configured in accordance with various embodiments of the present technology. As shown, semiconductor device 420 includes a plurality of semiconductor dies 400 and a substrate 452. The plurality of semiconductor dies 400 are identified individually in FIG. 4 as semiconductor dies 400a-400f. One or more of the semiconductor dies 400a-400f can be examples of the semiconductor die 100 of FIGS. 1A and 1B, the semiconductor die 200 of FIGS. 2A-3, and/or other semiconductor dies configured in accordance with embodiments of the present technology. Although six semiconductor dies 400 are shown in the illustrated embodiment, semiconductor devices configured in accordance with other embodiments of the present technology can include any number of semiconductor dies, such as one, two, three, four, five, or more than six semiconductor dies. Additionally, or alternatively, although shown with substrate 452 in the illustrated embodiment, semiconductor devices configured in accordance with other embodiments of the present technology can include more than one substrate.

As shown in FIG. 4, the semiconductor dies 400a-400f are arranged in a stack 456 positioned over (e.g., bonded to, carried by) the substrate 452. Each of the semiconductor dies 400a-400f can be coupled to the substrate 452 via one or more through-substrate vias 458 (“TSVs 458”). The TSVs 458 can allow each of the semiconductor dies 400a-400f of the stack 456 to communicate data, such as (a) between one of the semiconductor dies 400a-400f and the substrate 452, (b) between two or more of the semiconductor dies 400a-400f, and/or (c) between one or more of the semiconductor dies 400a-400f and an external device communicably coupled to the one or more of the semiconductor dies 400a-400f via the substrate 452. Although shown as arranged in a single stack 456 in FIG. 4, in other embodiments of the present technology, the semiconductor dies 400a-400f can be arranged in multiple stacks positioned over the substrate 452. In these and other embodiments, various ones of the semiconductor dies 400a-400f can be arranged (a) side-by-side (or laterally offset) from various other ones of the semiconductor dies 400a-400f and/or (b) side-by-side (or laterally offset) from the substrate 452. Other configurations of the semiconductor dies 400a-400f relative to the substrate 452 and/or to each other are of course possible and within the scope of the present technology. For example, the substrate 452 can be positioned on or over all or a subset of the semiconductor dies 400a-400f (e.g., such that the substrate 452 is stacked on or carried by all or the subset of the semiconductor dies 400a-400f).

In some embodiments, the semiconductor dies 400a-400f include a first type of die. For example, one or more of the semiconductor dies 400a-400f can be memory dies that include a plurality of memory cells for storing data. As specific examples, all or a first subset of the semiconductor dies 400a-400f can be non-volatile memory dies (e.g., NAND dies), all or a second subset of the semiconductor dies 400a-400f can be volatile memory dies (e.g., DRAM dies), and/or all or a third subset of the semiconductor dies 400a-400f can be combination dies (e.g., having volatile and non-volatile storage elements). In these and other embodiments, one or more of the semiconductor dies 400a-400f can be non-memory dies and/or another suitable type of die.

The substrate 452 can be a carrier substrate, an interposer, a printed circuit board (PCB) or the like. In other embodiments, the substrate 452 can be a second type of die. For example, the substrate 452 can be an interface die (also referred to herein as a “base die,” a “logic die,” and the like). In these and other embodiments, the substrate 452 can be an integrated circuit, an application processor, or a host device (e.g., a CPU, GPU, TPU, or other suitable type of controller, microcontroller, processor, or microprocessor). In these and still other embodiments, the substrate 452 can be a memory die, such as a non-voltage memory die (e.g., a NAND die), a volatile memory die (e.g., a DRAM die), and/or a combination die. In still other embodiments, the substrate 452 can be a non-memory die and/or another suitable type of die.

As shown in FIG. 4, each of the semiconductor dies 400a-400f includes die overthinning detection circuitry 440. The die overthinning detection circuitry 440 can be an example of the die overthinning detection circuitry 340 described above with reference to FIG. 3, or of other die overthinning detection circuitry configured in accordance with embodiments of the present technology. Each instance of the die overthinning detection circuitry 440 can measure an amount of leakage current from a depletion region (not shown in FIG. 4) of a triple well structure (not shown in FIG. 4) of the respective one of the semiconductor dies 400a-400f when a reverse bias is applied to the triple well structure. In turn, leakage current measurements captured by the die overthinning detection circuitry 440 of the semiconductor dies 400a-400f can be used to identify which of the semiconductor dies 400a-400f (if any) have been overthinned/overpolished and pose reliability concerns. In some embodiments, when one of the semiconductor dies 400a-400f is identified as being overthinned/overpolished, that one of the semiconductor dies 400a-400f can be individually disabled or turned off, and the semiconductor device 420 can continue to operate with a reduced number of enabled/functioning semiconductor dies 400 in the stack 456.

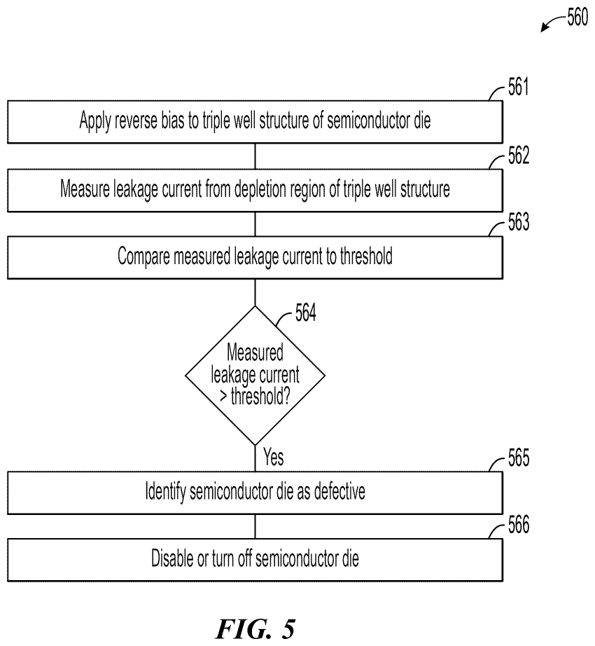

FIG. 5 is a flow diagram illustrating a method 560 of operating a semiconductor die in accordance with various embodiments of the present technology. The method 560 is illustrated as a series of blocks 561-566 or steps. All or a subset of one or more of the blocks 561-566 can be executed by devices or components of a semiconductor die (e.g., the semiconductor die 100 of FIGS. 1A and 1B, the semiconductor die 200 of FIGS. 2A-3, a semiconductor die 400 of FIG. 4, or another semiconductor die) and/or a semiconductor device (e.g., the semiconductor device 420 of FIG. 4 or another semiconductor device) configured in accordance with various embodiments of the present technology. For example, all or a subset of one or more of the blocks 561-566 can be executed by die overthinning detection circuitry (e.g., the die overthinning detection circuitry 340 of FIG. 3, the die overthinning detection circuitry 440 of FIG. 4, or other die overthinning detection circuitry configured in accordance with the present technology). In these and other embodiments, all or a subset of one or more of the blocks 561-566 can be performed while the semiconductor die is functioning in a specified operating mode (e.g., a die border test mode, a die overthinning detection test mode, an idle mode, an active mode). All or a subset of one or more of the blocks 561-566 of the method 560 can be executed in accordance with the description of FIGS. 1A-4 above and/or with the description below.

The method 560 begins at block 561 by applying a reverse bias to a triple well structure (e.g., the triple well structure 222 of FIGS. 2A-2C) of a semiconductor die. In some embodiments, applying the reverse bias includes applying the reverse bias using a voltage supply (e.g., the voltage supply 344 of FIG. 3). The voltage supply can be a high-voltage pump or another voltage supply included in or on the semiconductor die. In other embodiments, the voltage supply can be external to the semiconductor die, and/or applying the reverse bias can include applying the reverse bias via an external pin or contact of the semiconductor die. In some embodiments, applying the reverse bias includes applying the reverse bias between (a) a conductive contact (e.g., the conductive contact 210 of FIGS. 2A-3) positioned within (or coupled to) the triple well structure and (b) a contact (e.g., the contact 342 of FIG. 3) at or near a bottom surface of a substrate (e.g., the bottom surface 225 of the substrate 221 of FIGS. 2B and 3) of the semiconductor die. The conductive contact can be part of or separate from a metallization die border (e.g., the metallization die border 110 of FIG. 1B) of the semiconductor die. In these and other embodiments, applying the reverse bias can include applying a voltage on the order of 20V or greater.

At block 562, the method 560 continues by measuring an amount of leakage current from a depletion region of the triple well structure (e.g., the depletion region 227 of the triple well structure 222 of FIGS. 2A-3). In some embodiments, measuring the amount of leakage current includes measuring the amount of leakage current using a current meter (e.g., the current meter 346 of FIG. 3). The current meter can be included in or on the semiconductor die. In other embodiments, the current meter can be external to the semiconductor die, and/or measuring the amount of leakage current can include measuring the amount of leakage current via an external pin or contact of the semiconductor die. In some embodiments, measuring the amount of leakage current includes measuring the amount of leakage current while applying the reverse bias to the triple well structure at block 561.

At block 563, the method 560 continues by comparing the measured amount of leakage current to a threshold leakage current value. In some embodiments, the threshold leakage current value can be predetermined or preset. For example, the threshold leakage current value can be set at a value that is greater than leakage current typically observed in a similar semiconductor die that is (i) known not to be overthinned/overpolished and/or (ii) known not to include defects in the depletion region of a triple well structure of the similar semiconductor die. Continuing with this example, the threshold leakage current value can therefore be set at a value at or below which a semiconductor die is likely not overthinned/overpolished or is likely to include a depletion region devoid of defects. Additionally, or alternatively, the threshold leakage current value can be set at a value at or above which the semiconductor die is likely overthinned/overpolished or is likely to include a depletion region with defects.

In some embodiments, comparing the measured amount of leakage current to the threshold leakage current value can occur inside the semiconductor die. In other embodiments, comparing the measured amount of leakage current to the threshold leakage current value can occur external to the semiconductor die. For example, leakage current measurements captured by the current meter can be communicated to a semiconductor device that incorporates the semiconductor die and/or to a host device operably coupled to the semiconductor die. In turn, the semiconductor device or host device can perform the comparison.

At block 564, the method 560 determines whether the leakage current measured at block 562 is greater than (or equal to) the threshold leakage current value. If the method 560 determines that the measured leakage current is not greater than (or equal to) the threshold leakage current value (block 564: No), the method 560 (i) can determine that the semiconductor die is likely not overthinned/overpolished or is likely to include a depletion region devoid of defects, and/or (ii) can terminate. On the other hand, if the method 560 determines that the measured leakage current is greater than (or equal to) the threshold leakage current value (block 564: Yes), the method 560 can proceed to block 565.

In some embodiments, comparing the measured amount of leakage current to the threshold leakage current value (block 563) and/or determining whether the leakage current measured at block 562 is greater than (or equal to) the threshold leakage current value (block 564) can occur inside the semiconductor die. In other embodiments, comparing the measured amount of leakage current to the threshold leakage current value (block 563) and/or determining whether the leakage current measured at block 562 is greater than (or equal to) the threshold leakage current value (block 564) can occur external to the semiconductor die. For example, leakage current measurements and/or threshold comparison results can be communicated from the semiconductor die to a semiconductor device that incorporates the semiconductor die and/or to a host device operably coupled to the semiconductor die. In turn, the semiconductor device or host device can perform the comparison to the threshold value and/or determine whether the measured leakage current is greater than (or equal to) the threshold value.

At block 565, the method 560 identifies the semiconductor die as defective. Identifying the semiconductor die as defective can be based at least in part on the results of blocks 563 and 564. In some embodiments, identifying the semiconductor die as defective includes identifying the semiconductor die as being overthinned/overpolished, as including a depletion region with defects, and/or as exhibiting leakage current at levels that pose reliability issues/concerns.

At block 566, the method 560 continues by disabling or turning off the semiconductor die. For example, in embodiments in which the semiconductor die is implemented in a stack of semiconductor dies (e.g., the stack 456 of the semiconductor dies 400a-400f of FIG. 4), disabling or turning off the semiconductor die can include bypassing the semiconductor die (i) such that the semiconductor die is not powered or is not used to store data and/or (ii) such that a semiconductor device incorporating the stack can continue to operate with the remaining enabled/functioning/non-defective semiconductor dies in the stack.

In some embodiments, identifying the semiconductor die as defective (block 565) and/or disabling or turning off the semiconductor die (block 566) can occur inside the semiconductor die. In other embodiments, identifying the semiconductor die as defective (block 565) and/or disabling or turning off the semiconductor die (block 566) can occur external to the semiconductor die. For example, based at least in part on the results of blocks 563 and 564, a semiconductor device that incorporates the semiconductor die and/or a host device operably coupled to the semiconductor die can identify the semiconductor die as defective and/or disable/turn off the semiconductor die.

Although the blocks 561-566 of the method 560 are described and illustrated in a particular order, the method 560 of FIG. 5 is not so limited. In other embodiments, all or a subset of one or more of the blocks 561-566 of the method 560 can be performed in a different order. In these and other embodiments, all or a subset of any of the blocks 561-566 can be performed before, during, and/or after all or a subset of any of the other blocks 561-566. Furthermore, a person skilled in the art will readily appreciate that the method 560 can be altered and still remain within these and other embodiments of the present technology. For example, all or a subset of one or more of the block 561-566 can be omitted and/or repeated in some embodiments.

As a specific example, the method 560 is described above in the context of a semiconductor die implemented in a stack of semiconductor dies. Stated another way, one or more of the blocks 561-566 are described above as being performing at the die-level and/or post-packaging. One or more of the blocks 561-565 can be performed at a wafer-level and/or pre-packaging in some embodiments. For example, one or more of the blocks 561-565 can be performed at the wafer-level to detect defects (e.g., due to thermal effects, dislocation in silicon, etc.) encroaching into the depletion region of triple well structures of semiconductor dies within the wafer. In these embodiments, block 566 of the method 560 can be omitted, and a semiconductor die identified as defective at block 565 can be discarded (e.g., before being implemented in a stack or otherwise packaged).

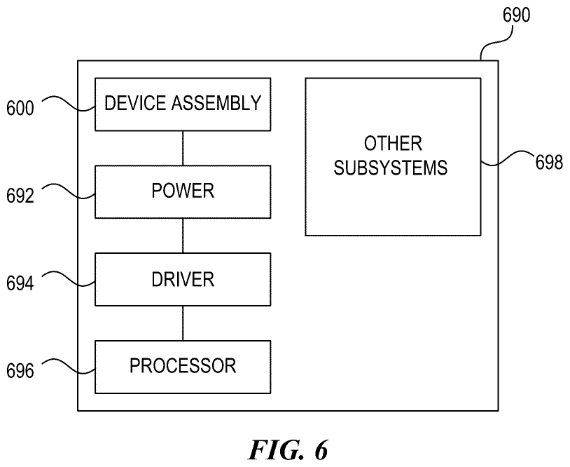

Any of the semiconductor devices described above with reference to FIGS. 1A-5 can be incorporated into any of a myriad of larger and/or more complex systems, a representative example of which is system 690 shown schematically in FIG. 6. The system 690 can include a semiconductor device assembly 600, a power source 692, a driver 694, a processor 696, and/or other subsystems or components 698. The semiconductor device assembly 600 can include semiconductor devices with features generally similar to those of the semiconductor devices described above. The resulting system 690 can perform any of a wide variety of functions, such as memory storage, data processing, and/or other suitable functions. Accordingly, representative systems 690 can include, without limitation, hand-held devices (e.g., mobile phones, tablets, digital readers, and digital audio players), computers, and appliances. Components of the system 690 may be housed in a single unit or distributed over multiple, interconnected units (e.g., through a communications network). The components of the system 690 can also include remote devices and any of a wide variety of computer readable media.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive of the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

In the detailed description of the present technology provided above, the term “through-silicon via” or “TSV” is used to generically describe an interconnect or via structure (a) that is used to electrically couple stacked substrates (e.g., one or more first dies and/or one or more second dies) to one another and/or (b) that is usable to vertically transmit electrical signals at least partway up or down a stack of substrates. In some embodiments, one or more substrates of a stack can, but need not, be formed of silicon. For example, the term “through-silicon via” or “TSV” as used herein can be used to describe an electrical connection that extends vertically at least partially through a substrate formed of silicon or another suitable material other than silicon. Thus, the term “through-silicon via” or “TSV” as used herein should be interpreted broadly to include an interconnect or via structure that extends vertically at least partially through one or more substrates formed of silicon or another suitable material.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments necessarily exhibit such advantages to fall within the scope of the technology. Accordingly, the disclosure and associated technology can encompass other embodiments not expressly shown or described herein.

We claim:

1. A semiconductor die, comprising:
a substrate;
a triple well structure positioned at least partially within the substrate and forming a depletion region within the substrate; and
circuitry configured to capture a measurement of an amount of leakage current from the depletion region while a reverse bias is applied across the triple well structure.

2. The semiconductor die of claim 1, wherein:
the substrate has a first side and a second side opposite the first side;
the semiconductor die further includes a first contact at the first side of the substrate and coupled the triple well structure;
the circuitry includes a second contact at the second side of the substrate; and
the reverse bias is applied across the triple well structure using the first and second contacts.

3. The semiconductor die of claim 2, wherein:
the semiconductor die includes a metallization die border positioned along a perimeter region of the semiconductor die; and
the first contact is part of the metallization die border.

4. The semiconductor die of claim 2, wherein:
the semiconductor die includes a metallization die border positioned along a perimeter region of the semiconductor die; and
the first contact is separate from the metallization die border.

5. The semiconductor die of claim 2, wherein:
the semiconductor die further includes an n+ region formed in or on the substrate; and
the first contact is coupled to the n+ region.

6. The semiconductor die of claim 2, wherein:
the semiconductor die further includes one or more external contacts; and
the first and second contacts are coupled to the one or more external contacts such that the reverse bias can be externally supplied to the semiconductor die and applied across the triple well structure.

7. The semiconductor die of claim 1, wherein the circuitry includes a current meter configured to capture the measurement of the amount of leakage current.

8. The semiconductor die of claim 1, wherein the circuitry includes a voltage supply configured to apply the reverse bias across the triple well structure.

9. The semiconductor die of claim 8, wherein the voltage supply includes a high-voltage pump.

10. The semiconductor die of claim 8, wherein the voltage supply is configured to apply the reverse bias across the triple well structure.

11. The semiconductor die of claim 1, wherein:
the substrate is a p-type substrate; and
the triple well structure includes a deep n-well.

12. The semiconductor die of claim 1, wherein the circuitry is further configured to determine that the semiconductor die is defective based at least in part on the measurement of the amount of leakage current.

13. A method, comprising:
measuring an amount of leakage current from a depletion region formed by a triple well structure in a semiconductor die, wherein measuring the amount of leakage current form the depletion region includes measuring the amount of leakage current while a voltage is applied across the triple well structure; and
identifying that the semiconductor die is defective based at least in part on the measured amount of leakage current from the depletion region.

14. The method of claim 13, further comprising applying the voltage across the triple well structure, wherein applying the voltage includes applying a reverse bias across the triple well structure.

15. The method of claim 13, further comprising disabling the semiconductor die based at least in part on identifying that the semiconductor die is defective.

16. A semiconductor device, comprising:
a substrate; and
a plurality of semiconductor dies arranged in a stack on the substrate, wherein each semiconductor die of the plurality includes
a substrate,
a triple well structure that forms a depletion region within the substrate, and
circuitry configured to measure an amount of leakage current from the depletion region while a voltage is applied across the triple well structure.

17. The semiconductor device of claim 16, wherein:
the substrate of each semiconductor die of the plurality has a first side and a second side opposite the first side;
each semiconductor die of the plurality further includes a first contact at the first side of the substrate and coupled the triple well structure;
the circuitry of each semiconductor die includes a second contact at the second side of the substrate; and
the voltage is applied across the triple well structure using the first and second contacts.

18. The semiconductor device of claim 17, wherein:
each semiconductor die of the plurality includes a metallization die border positioned along a perimeter region of the semiconductor die; and
the first contact of each semiconductor die is part of the metallization die border of that semiconductor die.

19. The semiconductor device of claim 16, wherein the circuitry of each semiconductor die of the plurality includes (a) a current meter configured to measure the amount of leakage current from the depletion region while the voltage is applied across the triple well structure, and (b) a voltage supply configured to apply the voltage across the triple well structure.

20. The semiconductor device of claim 16, wherein the semiconductor device is configured to (i) identify defective ones of the plurality of semiconductor dies based at least in part on comparisons of the measured amounts of leakage current to a threshold and (ii) individually disable the identified defective ones of the plurality of semiconductor dies.
